(19) United States
(12) Patent Application Publication
(10) Pub. No.: US 2022/0059807 A1
(43) Pub. Date: Feb. 24, 2022

(54) ELECTRODE AND FLUORESCENCE ORGANIC LIGHT-EMITTING DIODE COMPRISING THE ELECTRODE

(71) Applicant: KOREA UNIVERSITY RESEARCH AND BUSINESS FOUNDATION, Seoul (KR)

(72) Inventors: Byeong Kwon JU, Seoul (KR); Ha HWANG, Seoul (KR); Im Hyuk SHIN, Seoul (KR); In Seon YOON, Seoul (KR); Deok Hyun YOON, Seoul (KR); Soo Jong PARK, Seoul (KR)

(73) Assignee: KOREA UNIVERSITY RESEARCH AND BUSINESS FOUNDATION, Seoul (KR)

(21) Appl. No.: 17/316,841

(22) Filed: May 11, 2021

(30) Foreign Application Priority Data
Aug. 24, 2020 (KR) 10-2020-0106158

(51) Int. Cl. H01L 51/52

(52) U.S. Cl. CPC H01L 51/5293; H01L 2251/533; H01L 51/5221; H01L 51/5206

(57) ABSTRACT

Disclosed are an electrode for a fluorescence organic light-emitting diode including a magnetic material and a fluorescence organic light-emitting diode including the electrode.

The electrode for the fluorescence organic light-emitting diode according to an embodiment of the present disclosure may include a first paramagnetic material layer formed on an organic layer; a ferromagnetic material layer formed on the first paramagnetic material layer; and a second paramagnetic material layer formed on the ferromagnetic material layer.

### CROSS-REFERENCE TO RELATED APPLICATION

This present application claims priority under 35 U.S.C. § 119(a) to Korean Patent Application No. 10-2020-0106158 filed on Aug. 24, 2020 in the Korean Intellectual Property Office on Mar. 10, 2021, the entire contents of which are incorporated herein by reference.

### BACKGROUND

### (a) Technical Field

The present disclosure relates to an electrode and an organic light-emitting diode including the electrode, and more particularly, to an electrode for a fluorescence organic light-emitting diode including a magnetic material and a fluorescence organic light-emitting diode including the electrode.

### (b) Background Art

An electric light-emitting diode that is in the spotlight recently in the field of display, particularly an organic light-emitting diode is a device using light generated when electrons and holes are combined to extinct the light emission.

Organic light-emitting diodes (OLED) is in spotlight in display and illumination markets due to excellent color reproduction range, a high contrast ratio, quick response speed, a bending property, etc.

In the production ratio of excitons generated in a light-emitting layer of the OLED, since a ratio of singlet and triplet is 1:3 by the quantum mechanical statistics, the internal quantum efficiency (IQE) of fluorescence OLEDs contributing to emitting light by only singlet excitons is theoretically limited to at least 25%, and the IQE of phosphorescence OLEDs contributing to emitting light by both singlet and triplet excitons reaches 100%. In related prior arts, there is Korean Patent Registration No. 10-1397109.

The phosphorescence OLEDs having high light efficiency have been used in the overall industry, but the phosphorescent light-emitting type has a disadvantage that quenching between excitons severely occurs by a long lifetime (to ms) of triplet excitons, so that the lifetime of the OLED device is shortened and the efficiency at high luminance is rapidly reduced. In particular, in the case of blue phosphorescence OLEDs, since the energy of the triplet excitons is larger than the bond dissociation energy of organic molecules, a molecular dissociation phenomenon more frequently occurs than red and green to break the bonds between molecules or lose original characteristics of molecules. As a result, the blue phosphorescence OLED has a very low lifetime compared to green and red phosphorescence OLEDs.

In order to solve the lifetime problem of the blue phosphorescence OLED, studies such as graded doping have been conducted to reduce quenching of triplet excitons by increasing an emission area. However, the blue phosphorescence OLED has a lifetime characteristic about 100 times shorter than the blue fluorescence OLED and the development of organic materials used in the blue phosphorescent emission is not easy due to large energy of the excitons of the blue phosphorescence OLED. As a result, even though the blue OLED used in a mobile display have low efficiency, fluorescence OLED having a relatively good lifetime characteristic have been used and various studies for improving the efficiency of the fluorescence OLED are required.

The above information disclosed in this Background section is only for enhancement of understanding of the background of the disclosure and therefore it may contain information that does not form the prior art that is already known in this country to a person of ordinary skill in the art.

### SUMMARY OF THE DISCLOSURE

An object of the present disclosure is to provide an electrode for a fluorescence organic light-emitting diode with improved light efficiency and lifetime, and a fluorescence organic light-emitting diode including the electrode.

Another object of the present disclosure is to provide an electrode for a fluorescence organic light-emitting diode capable of aligning spin directions in one direction by using a ferromagnetic material and a fluorescence organic light-emitting diode including the electrode.

According to an aspect of the present disclosure to achieve the object, there is disclosed an electrode for a fluorescence organic light-emitting diode including: a first paramagnetic material layer formed on an organic layer; a ferromagnetic material layer formed on the first paramagnetic material layer; and a second paramagnetic material layer formed on the ferromagnetic material layer.

According to another aspect of the present disclosure to achieve the object, there is disclosed a fluorescence organic light-emitting diode including: a substrate; a first electrode formed on the substrate; an organic layer formed on the first electrode; and a second electrode formed on the organic layer, wherein the organic layer is formed of at least one layer including a light-emitting layer, and the second electrode includes: a first paramagnetic material layer; a ferromagnetic material layer formed on the first paramagnetic material layer; and a second paramagnetic material layer formed on the ferromagnetic material layer.

According to the embodiment of the present disclosure, the electrode for the fluorescence organic light-emitting diode and the fluorescence organic light-emitting diode including the electrode can overcome theoretical limitations of the light efficiency of fluorescence organic light-emitting diodes (OLED) by a simple process of inserting a ferromagnetic material electrode.

According to the embodiment of the present disclosure, it is possible to improve the light efficiency and lifetime of the fluorescence organic light-emitting diode even by using an organic material and an organic layer structure of the OLED as it is.

It should be understood that the effects of the present disclosure are not limited to the effects described above, but include all effects that can be deduced from the detailed description of the present disclosure or configurations of the disclosure described in appended claims.

### BRIEF DESCRIPTION OF THE DRAWINGS

FIGS. 1A-1B are diagrams describing a configuration and an emission mechanism of conventional organic light-emitting diodes (OLED).

FIGS. 2A-2B are diagrams for describing a spin current injection OLED structure using a ferromagnetic material electrode according to an embodiment of the present disclosure.

FIG. 3 is a schematic diagram of an OLED structure inserted with a ferromagnetic material electrode according to an embodiment of the present disclosure.

FIG. 4 is a graph showing electro-optic characteristics of the OLED in FIG. 3.

FIG. 5 is a graph of comparing transmittances of ITO and Ni electrodes according to an embodiment of the present disclosure.

FIG. 6 is a schematic diagram of a fluorescence OLED structure inserted with a hybrid type ferromagnetic material electrode in which a ferromagnetic material and a paramagnetic material are mixed according to another embodiment of the present disclosure.

FIG. 7 is a diagram for describing an optimized thickness of a paramagnetic material layer in a cathode having a multilayer structure illustrated in FIG. 6.

FIG. 8 is a graph showing reflectance of the cathode having the multilayer structure illustrated in FIG. 6 analyzed through FDTD optical simulation.

FIGS. 9A-9D are graphs showing emission characteristics of the OLED to which the cathode having the multilayer structure illustrated in FIG. 6 is applied.

FIG. 10 is a graph showing magnetization characteristics of the OLED to which the cathode having the multilayer structure illustrated in FIG. 6 is applied.

### DETAILED DESCRIPTION

Hereinafter, an electrode for a solar-radiation fluorescence organic light-emitting diode and a fluorescence organic light-emitting diode including the electrode according to an embodiment of the present disclosure will be described with reference to the accompanying drawings.

A singular form used in this specification may include a plural form unless otherwise clearly noted in the context. In this specification, the term such as “comprising” or “including” should not be interpreted as necessarily including all various components or various steps disclosed in the specification, and it should be interpreted that some component or some steps among them may not be included or additional components or steps may be further included.

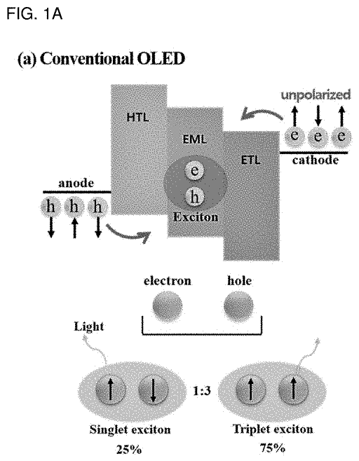

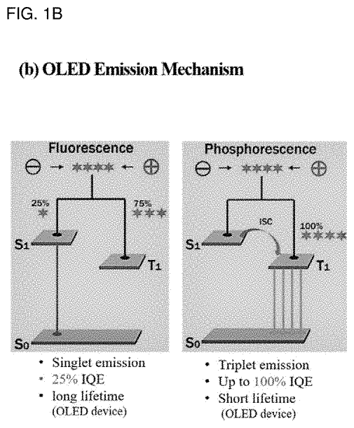

FIG. 1 is a diagram for describing a configuration and an emission mechanism of conventional organic light-emitting diodes (OLED).

FIG. 1A illustrates a spin-polarized characteristic of a carrier injected into an organic material and a production ratio of singlet and triplet excitons in a conventional OLED and FIG. 1B illustrates fluorescence and phosphorescence emission mechanisms of the OLED.

As illustrated, when carriers (electrons and holes) are injected into an OLED device by using a conventional paramagnetic material electrode, spin directions of the carriers are unpolarized. When the carriers having the unpolarized spin directions are injected into a light-emitting layer of the OLED, a production ratio of excitons formed in the light-emitting layer has a ratio of singlet and triplet of 1:3 by quantum mechanical spin statistics. As a result, the internal quantum efficiency (IQE) of the fluorescence OLED emitting light by using only singlet excitons is limited to at most 25%.

Hereinafter, in the embodiment, it will be described a method of increasing the IQE of the fluorescence OLED by injecting carriers aligned in one spin direction into an OLED device using a ferromagnetic material, and by increasing the production ratio of singlet excitons in the light-emitting layer.

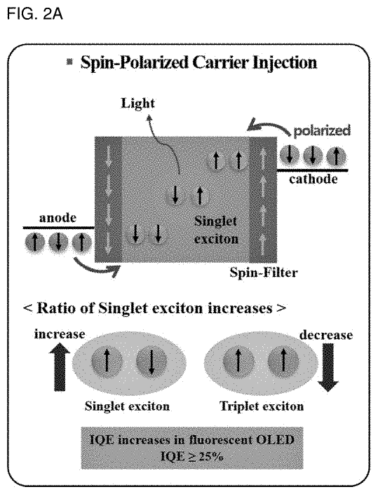

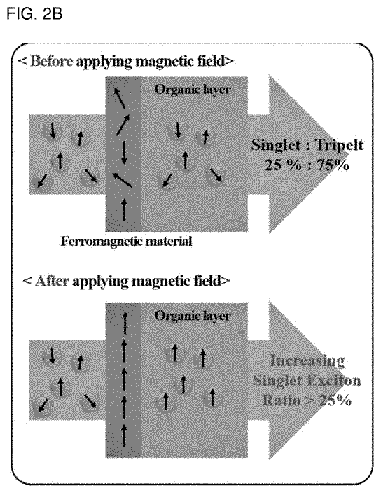

FIG. 2 is a diagram for describing a spin current injection OLED structure using a ferromagnetic material electrode according to an embodiment of the present disclosure.

FIG. 2A is a schematic diagram of spin-polarized charge carrier injection and FIG. 2B is a diagram illustrating a magnetization direction and a spin-polarized alignment mechanism in the ferromagnetic material depending on application of an external magnetic field.

As illustrated, FIG. 2A shows an OLED device structure in which a ferromagnetic material (Ni, Co, Fe, etc.) is used as an electrode. Before the carriers pass through the ferromagnetic material electrode, the spin-polarized directions are randomly up or down, but the carriers passing through the ferromagnetic material electrode have a pattern of passing while the spin-polarized directions are aligned depending on the magnetization direction in the ferromagnetic material.

It can be confirmed through FIG. 2B that the magnetization direction inside the ferromagnetic material has a characteristic to be aligned in the external magnetic field direction when the magnetic field is applied from the outside. When the charge carriers pass through the ferromagnetic material electrode after the external magnetic field is applied to the ferromagnetic material, momentum delivery (spin forwarding torque) occurs between the spins of the carriers and the magnetization direction of the ferromagnetic material, so that the spin-polarized directions of the charge carriers are aligned in one direction. As a result, the carriers in which the spin directions are aligned may be injected into the light-emitting layer of the OLED and the carriers with the aligned spin directions form excitons to increase the production ratio of singlet excitons.

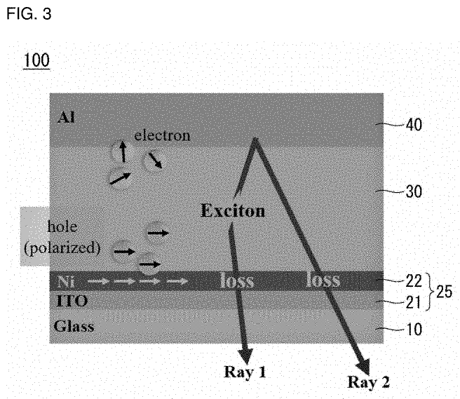

FIG. 3 is a schematic diagram of a fluorescence OLED structure inserted with a ferromagnetic material electrode according to an embodiment of the present disclosure.

As illustrated, a fluorescence OLED 100 includes a glass substrate 10, an anode (positive electrode) 25, an organic layer 30, and a cathode (negative electrode) 40.

In the anode 25, a ferromagnetic material layer 22 may be formed on an ITO electrode 21. The ferromagnetic material layer 22 may refer to a thin film layer made of a ferromagnetic material. The ferromagnetic material may include at least one of Ni, Co, Fe, and Mn. The magnetic material includes, for example, Ni, Co, Fe, Mn, Bi, FeO—Fe₂O₃, NiO—Fe₂O₃, CuO—Fe₂O₃, MgO—Fe₂O₃, MnBi, MnSb, MnAs, MnO—Fe₂O₃, Y₃Fe₂O₃, CrO₂, EuO, etc. These magnetic materials may be used alone or in a combination of two types or more. Hereinafter, in the embodiment, Ni will be described as an example of the ferromagnetic material. When a magnetic field is applied to the ferromagnetic material electrode, spin-polarized directions are aligned in one direction.

The organic layer 30 is formed on the Ni ferromagnetic material layer 22. A light-emitting layer in which holes and electrons are combined to extinct the light emission is included in the organic layer 30. The anode 25 is a positive electrode for injecting holes, and the cathode 40 is a negative electrode for injecting electrons.

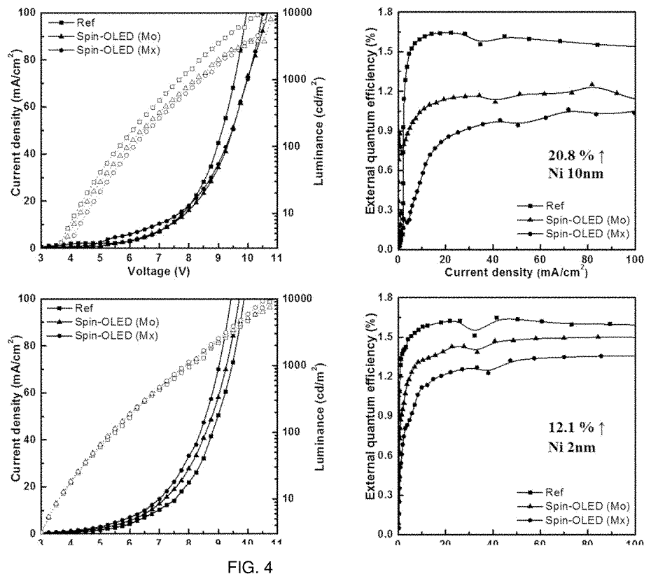

FIG. 4 is a graph showing electro-optic characteristics of the OLED in FIG. 3.

FIG. 4 is a graph showing comparing results of measuring device efficiency before (blue) and after (red) applying a magnetic field to a ferromagnetic material electrode.

As illustrated, it can be confirmed that the external quantum efficiency (EQE), optical efficiency of the OLED device is improved by 12% to 20% after applying as compared to before applying the magnetic field. This is determined that the carriers (holes) in which the spin directions are aligned are injected into the organic material to increase the production ratio of the singlet excitons.

However, since the light generated in the light-emitting layer passes through the Ni thin film, an absolute value (efficiency value) of the efficiency is low as compared with an OLED device (Ref, black) into which the ferromagnetic material thin film is not inserted by generating the light loss.

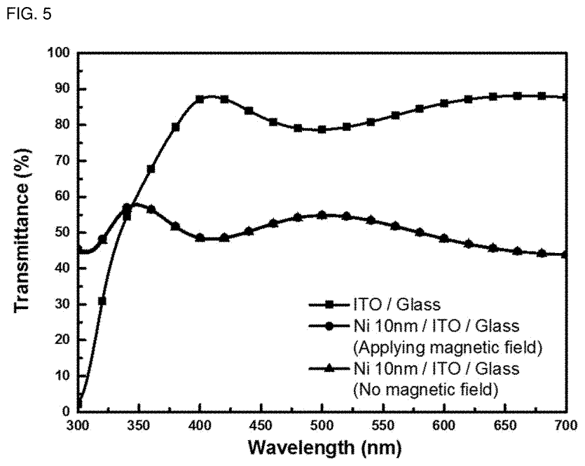

FIG. 5 is a graph of comparing transmittances of ITO and Ni electrodes according to an embodiment of the present disclosure.

As can be seen in FIG. 5, the ferromagnetic material electrode generally has a low transmittance. Referring to FIG. 3, when the light generated from the light-emitting layer of the fluorescence OLED is emitted to the outside, the light necessarily passes through the ferromagnetic material layer 22, so that the light loss occurs due to the low transmittance of the ferromagnetic material. Therefore, structural improvement is required when applying the ferromagnetic material electrode to the OLED.

Hereinafter, a hybrid type ferromagnetic material electrode in which a ferromagnetic material and a paramagnetic material are mixed will be described.

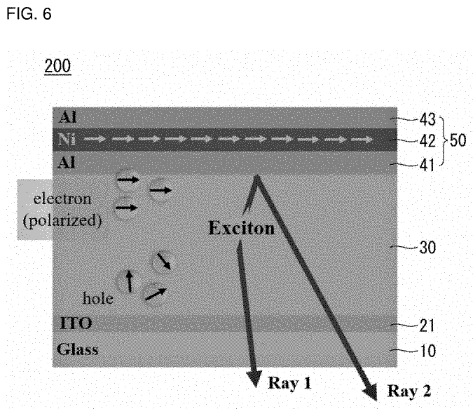

FIG. 6 is a schematic diagram of a fluorescence OLED structure inserted with a hybrid type ferromagnetic material electrode in which a ferromagnetic material and a paramagnetic material are mixed according to another embodiment of the present disclosure.

As illustrated, a fluorescence OLED 200 may include a glass substrate 10, an anode 21, an organic layer 30, and a cathode 50.

The anode 21 is formed on the glass substrate 10. The anode 21 may be composed of an ITO electrode. The ITO electrode 21 may be formed by a sputtering method or a deposition method.

The organic layer 30 is formed on the ITO electrode 21. A light-emitting layer in which holes and electrons are combined to extinct the light emission is included in the organic layer 30. The anode 21 is a positive electrode for injecting holes, and the cathode 50 is a negative electrode for injecting electrons.

The cathode 50 may be composed of a hybrid type ferromagnetic material electrode mixed with a paramagnetic material. The hybrid ferromagnetic material electrode has a shape in which the paramagnetic material is surrounded outside the ferromagnetic material.

The cathode 50 may include a first paramagnetic material layer 41, a ferromagnetic material layer 42, and a second paramagnetic material layer 43. The first paramagnetic material layer 41 and the second paramagnetic material layer 43 may refer to thin film layers formed of a paramagnetic material. When the paramagnetic material is a material which is slightly magnetized when the magnetic field is applied and is not magnetized when the magnetic field is removed. The paramagnetic material may include at least one of mixtures of Al, Sn, Pt, Ir, Ag, and Mg. Hereinafter, in the embodiment, aluminum (Al) having high reflectance will be described as an example of the paramagnetic material.

The cathode 50 is an electrode having a multilayer structure, and has a shape in which the first paramagnetic material layer 41 is formed below the ferromagnetic material layer 42 and the second paramagnetic material layer 43 is formed on the ferromagnetic material layer 42.

When an external magnetic field is applied to the ferromagnetic material, Ni, the magnetization direction inside the ferromagnetic material is aligned in one direction and the carriers passing through the ferromagnetic material proceeds while the spin direction are aligned in one direction. Generally, since the carriers with the aligned spin directions may pass through an Al layer without losing the spin directions, the carriers move to the light-emitting layer without losing the spin information to increase the production ratio of singlet excitons in the light-emitting layer. In general, since Al has a high reflectance, the light generated in the light-emitting layer is reflected and directed on an Al surface, so that the light loss does not occur. As such, the hybrid ferromagnetic material electrode electrically increases the singlet production ratio by injecting spin-polarized carriers through the Ni layer and the Al layer optically serves as a reflector, so that the light loss does not occur.

Meanwhile, since the light is emitted to the anode 21 side, the intensity of the light may be reduced when the paramagnetic material is formed in the anode 21. Accordingly, the paramagnetic material is not formed in the anode 21.

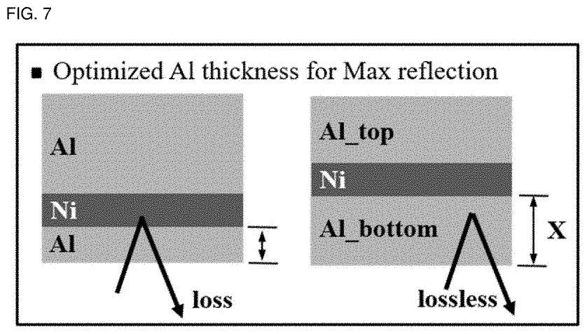

FIG. 7 is a diagram for describing an optimized thickness of a paramagnetic material layer in a cathode having a multilayer structure illustrated in FIG. 6.

As illustrated, when the thickness of the Al layer serving as the reflector is too thin, the Al layer may not serve as a reflective film well, and when the thickness is too thick, the carriers with the aligned spin directions move inside the Al layer to lose the spin information.

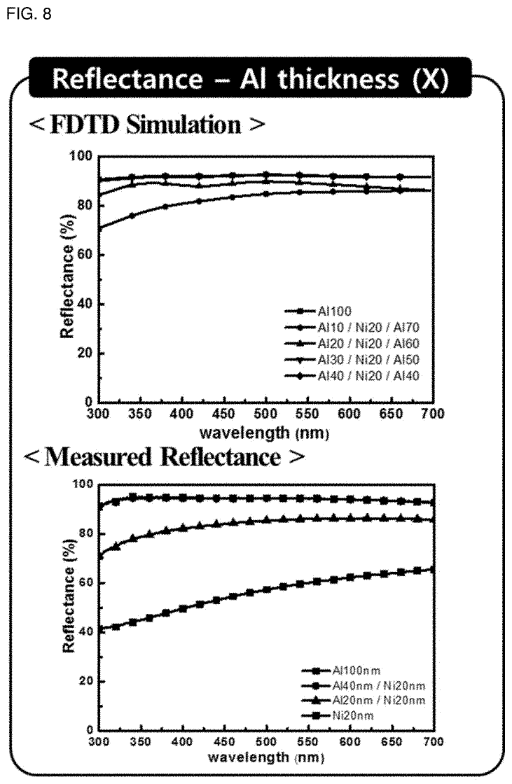

FIG. 8 is a graph showing reflectance of the cathode having the multilayer structure illustrated in FIG. 6 analyzed through FDTD optical simulation.

FIG. 8 is a graph showing a result of performing optical simulation (FDTD) to determine an optimized thickness. Through this, it was expected that the thickness of an Al_bottom layer had an optimized optical characteristic (reflectance) at about 40 nm. Further, when the thickness of the Al_bottom layer is about 40 nm, the thickness of the ferromagnetic material layer 42 may be an optimum value of about 20 nm.

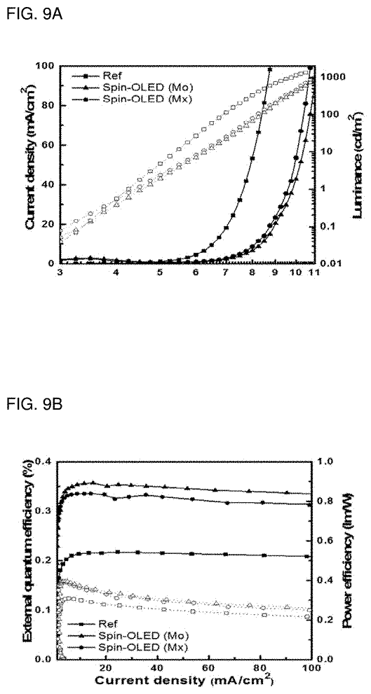

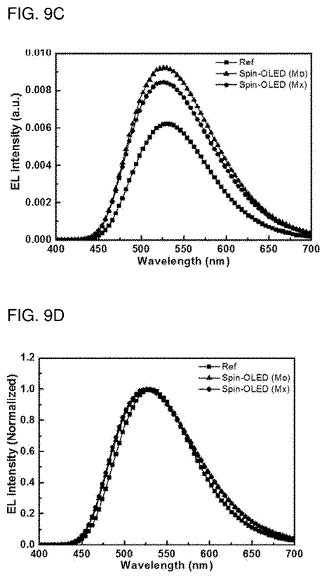

FIG. 9 is a graph showing emission characteristics of the OLED to which the cathode having the multilayer structure illustrated in FIG. 6 is applied.

FIG. 9A illustrates a current-voltage-luminance characteristic, FIG. 9B illustrates an external quantum efficiency (EQE)-current density characteristic, FIG. 9C illustrates a current-voltage-luminance characteristic at an Ni thickness of 2 nm, and FIG. 9D illustrates an EQE-current density characteristic.

In FIG. 9, the cathode electrode shows an electro-optic characteristic of the OLED in which a hybrid ferromagnetic material electrode is included in the cathode electrode. The results of measuring device efficiency before (blue) and after (red) applying a magnetic field to a ferromagnetic material electrode were compared. The device efficiency was largely increased both before and after applying the magnetic field as compared with a Ref (black) device, and it is determined because the spin-polarized charge carriers are injected into the light-emitting layer by applying the hybrid ferromagnetic material electrode to increase the production ratio of singlet excitons. On the other hand, when the magnetic field is applied to the device as compared with before applying the magnetic field to the device, the light efficiency of the device is further increased. This is a phenomenon that the magnetization of the ferromagnetic material inside the hybrid electrode is saturated by applying the external magnetic field.

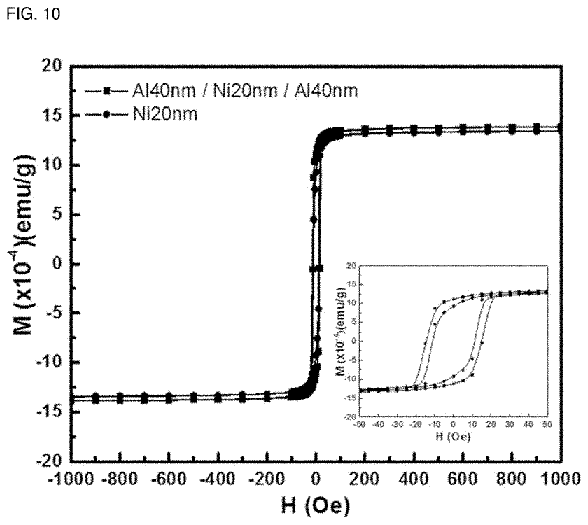

FIG. 10 is a graph showing magnetization characteristics of the OLED to which the cathode having the multilayer structure illustrated in FIG. 6 is applied.

As can be seen through FIG. 10, a ferromagnetic material thin film has a predetermined amount of magnetization M even when there is no external magnetic field (H=0), and this is fully saturated by applying the external magnetic field (H=1000). Therefore, even if the external magnetic field is not applied to a spin-OLED device, the magnetization direction of the ferromagnetic material thin film is aligned to some extent, so that the spin-polarized charges are injected. As a result, the light efficiency may be improved before applying the external magnetic field to the hybrid ferromagnetic material electrode, and when the external magnetic field is applied, the magnetization is saturated and smaller light efficiency is further improved.

As described above, according to the embodiment of the present disclosure, in the electrode for the fluorescence organic light-emitting diodes and the fluorescence organic light-emitting diodes including the electrode, it is possible to overcome theoretical limitations of the light efficiency of fluorescence organic light-emitting diodes (OLED) by a simple process of inserting a ferromagnetic material electrode.

According to the embodiment of the present disclosure, it is possible to improve the light efficiency and lifespan of the fluorescence organic light-emitting diodes even by using an organic material and an organic layer structure of the OLED as it is.

The electrode for the fluorescence organic light-emitting diodes and the fluorescence organic light-emitting diodes including the electrode described above are not applied to limit the configuration and the method of the embodiments described above, but the embodiments may also be configured by selectively combining all or some of the embodiment so as to make various modifications.

What is claimed is:

1. An electrode for a fluorescence organic light-emitting diode, comprising:
a first paramagnetic material layer formed on an organic layer;
a ferromagnetic material layer formed on the first paramagnetic material layer; and
a second paramagnetic material layer formed on the ferromagnetic material layer.

2. The electrode for the fluorescence organic light-emitting diode of claim 1, wherein the ferromagnetic material layer is made of a ferromagnetic material and the ferromagnetic material is made of at least one of Ni, Co, Fe, and Mn, and
the first paramagnetic material layer and the second paramagnetic material layer are made of a paramagnetic material and the paramagnetic material includes at least one of mixtures of Al, Sn, Pt, Ir, Ag, and Mg.

3. The electrode for the fluorescence organic light-emitting diode of claim 2, comprising:
a cathode including the first paramagnetic material layer; a ferromagnetic material layer formed on the first paramagnetic material; and a second paramagnetic material layer formed on the ferromagnetic material.

4. The electrode for the fluorescence organic light-emitting diode of claim 3, further comprising:
an anode,
wherein in the anode, the paramagnetic material layer is not formed and only the ferromagnetic material layer is formed.

5. The electrode for the fluorescence organic light-emitting diode of claim 3, wherein the first paramagnetic material layer and the second paramagnetic material layer are thicker than the ferromagnetic material layer.

6. A fluorescence organic light-emitting diode, comprising:
a substrate;
a first electrode formed on the substrate;
an organic layer formed on the first electrode; and
a second electrode formed on the organic layer,
wherein the organic layer is formed of at least one layer including a light-emitting layer, and
the second electrode comprises:
a first paramagnetic material layer;
a ferromagnetic material layer formed on the first paramagnetic material layer; and
a second paramagnetic material layer formed on the ferromagnetic material layer.

7. The fluorescence organic light-emitting diode of claim 6, wherein the ferromagnetic material layer is made of a ferromagnetic material and the ferromagnetic material is made of at least one of Ni, Co, Fe, and Mn, and
the first paramagnetic material layer and the second paramagnetic material layer are made of a paramagnetic material and the paramagnetic material includes at least one of mixtures of Al, Sn, Pt, Ir, Ag, and Mg.

8. The fluorescence organic light-emitting diode of claim 7, wherein the first electrode is an anode, and the second electrode is a cathode.

9. The fluorescence organic light-emitting diode of claim 8, wherein in the first electrode, the paramagnetic material layer is not formed and only the ferromagnetic material layer is formed.

10. The fluorescence organic light-emitting diode of claim 8, wherein the first paramagnetic material layer and the second paramagnetic material layer are thicker than the ferromagnetic material layer.
